(19) United States
(12) Patent Application Publication
(10) Pub. No.: US 2014/0073128 A1
(43) Pub. Date: Mar. 13, 2014

(54) MANUFACTURING METHOD FOR METAL LINE

(71) Applicant: National Applied Research Laboratories, Taipei City (TW)

(72) Inventor: Chao-An JONG, Hsinchu (TW)

(73) Assignee: National Applied Research Laboratories, Taipei City (TW)

(21) Appl. No.: 14/079,947

(22) Filed: Nov. 14, 2013

Related U.S. Application Data
(63) Continuation-in-part of application No. 13/541,672, filed on Jul. 4, 2012.

(30) Foreign Application Priority Data
Feb. 7, 2013 (TW) 102104938

(51) Int. Cl. H01L 21/768

(52) U.S. Cl. CPC H01L 21/76841
USPC 438/643

(57) ABSTRACT

A method for manufacturing metal lines in a semiconductor device is provided. The method includes steps of: providing a substrate; forming a first barrier layer on the substrate; forming a sacrificial layer on the first barrier layer; forming an opening penetrating through the sacrificial layer to expose a portion of the first barrier layer; depositing a metal material on the exposed first barrier layer to form a metal line in the opening; removing the sacrificial layer and forming a second barrier layer over the resulting structure; etching the second barrier layer and the first barrier layer while remaining a barrier spacer on a sidewall of the metal line; and forming an insulating layer on the substrate and the barrier spacer. A semiconductor device having the metal lines produced by the method is also provided.

### CROSS-REFERENCE TO RELATED APPLICATIONS

This application is a Continuation in part of U.S. patent application Ser. No. 13/541672, filed on Jul. 4, 2012, now pending. The entirety of the above-mentioned patent application is hereby incorporated by reference herein and made a part of this specification.

### FIELD OF THE INVENTION

The present invention relates to a method for manufacturing metal lines and a semiconductor device having the metal lines, and more particularly to a method for manufacturing metal lines having high aspect ratio and a semiconductor device having metal lines produced by the same.

### BACKGROUND OF THE INVENTION

With modern develop of computing hardware, the required transistor density of chips rapidly increases and the corresponding line-width and dimension of semiconductor devices gradually decreases. On the premise of without increasing the device size, higher aspect ratio of metal lines is unavoidable. With miniaturization of the chips, for example, as device dimensions shrink to a 22 nm node and beyond, damascene copper schemes are facing difficulties in manufacturing processes and electrical properties, especially in controlling defect-free copper gap-filling and retaining reliability such as resistance to electro-migration (EM).

In today's damascene copper process, openings (e.g. trenches or vias in dual damascene process) to be filled are first formed in an insulating layer. Then, a diffusion barrier layer and a seed layer are sequentially formed on sidewalls and bottom areas of the openings to aid growth of metal lines in the openings by an electroplating process. However, the narrow and deep openings with high aspect ratio adversely affect the filling of metal, especially when the diffusion barrier layer and the seed layer cannot be arbitrarily thinned to provide adequate space for the filling In addition, overhang may occur when the seed layer is formed by physical vapor deposition (PVD). Therefore, the subsequent electroplating process may fail to completely fill the openings and consequentially result in voids within the contacts or wires.

Furthermore, since most metal material has accumulated at upper corners of the insulating layer before the electroplating material reaches the deep bottom during the electroplating process, the vertical growth speed of the metal lines cannot catch up the horizontal narrowing speed of the openings. Therefore, for the openings with high aspect ratio, the top of the openings is often sealed before the metal grows from the bottom to the top of the openings. Thus, the metal lines may involve internal voids, which lead to a higher resistance and a lower reliability.

Another solution is proposed to increase the space for the filling by decreasing the thickness of the diffusion barrier layer. However, for the copper lines, the relatively-thin barrier layer may not be able to effectively inhibit copper diffusion. Therefore, under the condition of certain thickness of the diffusion barrier layer, the copper lines with the diffusion barrier layer may have a rising resistance when the copper lines are getting thinner. Alternatively, reducing the thickness of the seed layer is another solution to increase the space for the filling or electroplating. However, it is difficult to uniformly form a continuous seed layer over the sidewalls of the openings due to limited coverage. Consequentially, copper may not be deposited on the uncovered portion of the sidewalls in the electroplating process, thereby resulting in the internal voids in the metal lines.

The formation of the high aspect-ratio opening is another challenge. By adopting the conventional patterning process to etch the dielectric layer to form the openings, the conditions should be controlled strictly, especially for forming the high aspect-ratio openings in porous low-k dielectric layers. For example, strict conditions involving smoothness of the etched sidewalls, etching selectivity, damage control of the etching stop layers and etch recover, etc. should be satisfied to guarantee the electrical performance of the semiconductor devices. These disadvantages or problems seriously affect the production yield of the semiconductor devices with scale-down dimension.

Accordingly, to solve the aforementioned problems, there is a need to provide a new manufacturing process for metal lines and a metal line structure produced by the same.

### SUMMARY OF THE INVENTION

An objective of the present invention is to provide a method for manufacturing metal lines in a semiconductor device. The openings for the metal lines are formed by a photolithography process rather than an etching process, thereby avoiding plasma damage incurred in the structure of the semiconductor device.

Another objective of the present invention is to provide a method for manufacturing metal lines in a semiconductor device. The metal lines are deposited and grow from bottom areas of the openings in the sacrificial layer, which effectively avoids occurrence of voids to enhance the electrical performance of the semiconductor device.

Still another objective of the present invention is to provide a semiconductor device having metal lines. Air gaps are formed during insulating layer deposition in narrow line pitch to reduce parasitic capacitance and enhance the electrical performance of the semiconductor device.

According to the present invention, a method for manufacturing metal lines in a semiconductor device includes steps of: providing a substrate; forming a first barrier layer on the substrate; forming a sacrificial layer on the first barrier layer; forming at least one opening in the sacrificial layer, wherein the at least one opening penetrates through the sacrificial layer to expose a first portion of the first barrier layer; depositing a metal material on the first portion of the first barrier layer to form at least one metal line in the at least one opening; removing the sacrificial layer to expose a second portion of the first barrier layer and forming a second barrier layer on a top area and a sidewall of the metal line and the second portion of the first barrier layer; etching the first barrier layer and the second barrier layer, and remaining the second barrier layer on the sidewall of the metal line as a barrier spacer and remaining the first barrier layer under the barrier spacer and the metal line; and forming an insulating layer on the substrate.

In an embodiment, the metal material is deposited on the first portion of the first barrier layer by an electroplating process, an electroless plating process, an electrophoretic process, or a supercritical fluid coating process with a bottom-to-up anisotropic growth from the first barrier layer toward an entrance of the opening

In an embodiment, an air gap is formed in the insulating layer which is formed non-conformally when a spacing between two adjacent barrier spacers, which define a space for accommodating the insulating layer, is less than 30 nm.

According to the present invention, another method for manufacturing metal lines in a semiconductor device includes steps of: providing a substrate; forming a barrier layer on the substrate; forming a sacrificial layer on the barrier layer; forming at least one opening in the sacrificial layer, wherein the opening penetrates through the sacrificial layer to expose a first portion of the barrier layer; depositing a metal material on the first portion of the barrier layer to form at least one metal line in the at least one opening; removing the sacrificial layer and a second portion of the barrier layer while remaining the first portion of the barrier layer; and forming an insulating layer on the substrate.

According to the present invention, a further method for manufacturing metal lines in a semiconductor device includes steps of: providing a substrate; forming a barrier layer on the substrate; forming a sacrificial layer on the barrier layer; forming at least one opening penetrating the sacrificial layer and exposing a first portion of the barrier layer; and forming a metal material on the first portion of the barrier layer with a bottom-to-up anisotropic growth from the barrier layer toward an entrance of the opening to form at least one metal line in the at least one opening.

According to the present invention, a semiconductor device having metal lines includes a substrate, an insulating layer disposed on the substrate, and a first metal line structure formed in the insulating layer by a damascence process. The first metal line structure includes a metal line, a first barrier layer and a second barrier layer. The first barrier layer is disposed between the substrate and the metal line, and the second barrier layer is disposed on a sidewall of the metal line and an exposed portion of the first barrier layer. The relatively thicker portion of the second barrier layer is near the first barrier layer.

In an embodiment, the semiconductor device further includes a second metal line structure formed in the insulating layer by the damascene process. An air gap is formed in the insulating layer between the first metal line structure and the second metal line structure when a spacing between the first metal line structure and the second metal line structure is less than 30 nm.

In an embodiment, the metal line is made of silver, tungsten, molybdenum, ruthenium, nickel or an alloy thereof.

In an embodiment, the second barrier layer is a taper-shaped sidewall spacer, and its taper-shaped end is in contact with a top portion of the metal line.

In summary, by adopting the photolithography process to form the openings for the damascene metal lines, complicated etching processes and the accompanying plasma damage are avoided. Furthermore, by using the electroplating process, electroless plating process or electrophoretic process to grow the metal lines on the first barrier layer at the bottom areas of the openings in a bottom-to-up manner, the height of the metal lines can be controlled to just completely fill the openings. Thus, a chemical mechanical polishing (CMP) process is not required to remove excess metal material. However, it is understood that the chemical mechanical polishing process may be still performed after the metal filling process to control the height of the metal lines or for planarization purpose. According to the present invention, no void occurs within the metal lines.

In addition, according to the present invention, air gaps are formed in the insulating layer between two adjacent metal lines with smaller spacing. Such structure has low parasitic capacitance and the final device including this metal line structure has an enhanced electrical performance and improved delay.

### BRIEF DESCRIPTION OF THE DRAWINGS

The present invention will become more readily apparent to those ordinarily skilled in the art after reviewing the following detailed description and accompanying drawings, in which:

FIGS. 1A-1F are schematic diagrams illustrating a method for manufacturing metal lines in a semiconductor device in accordance with an embodiment of the present invention;

FIG. 2 is a schematic diagram illustrating a semiconductor device in accordance with an embodiment of the present invention;

FIG. 3A is a schematic diagram illustrating a semiconductor device in accordance with another embodiment of the present invention; and

FIG. 3B is an enlarged diagram illustrating the dashed circle area in FIG. 3A.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

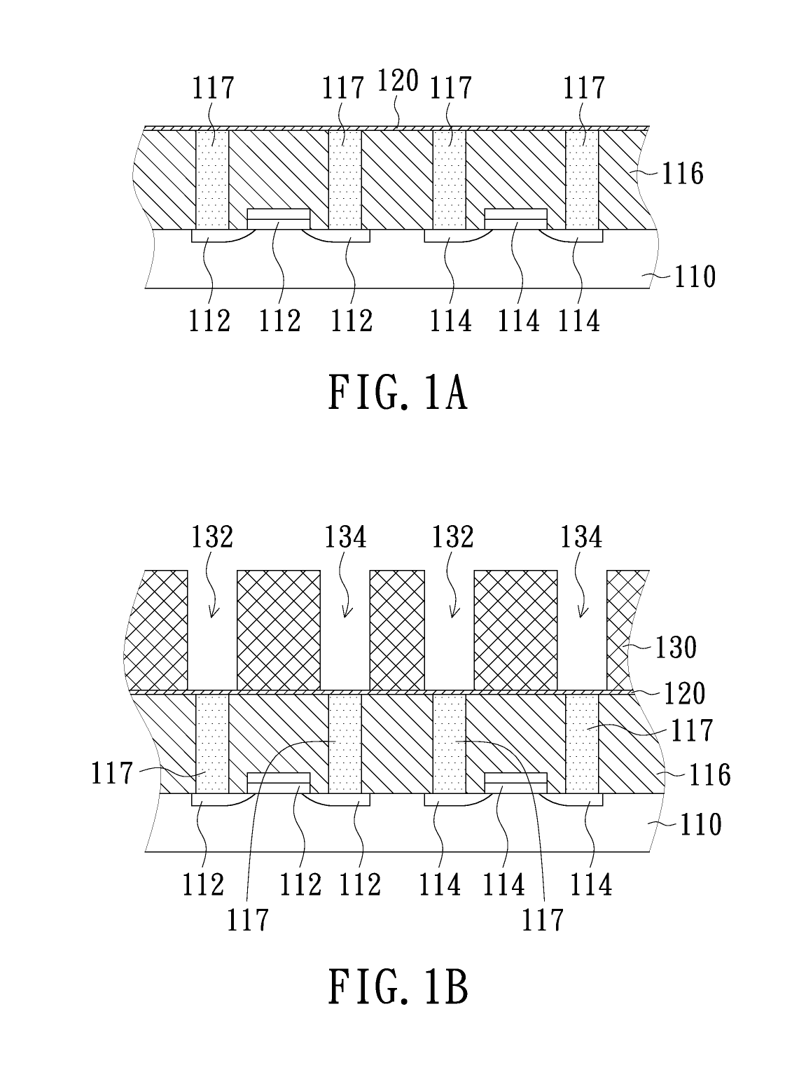

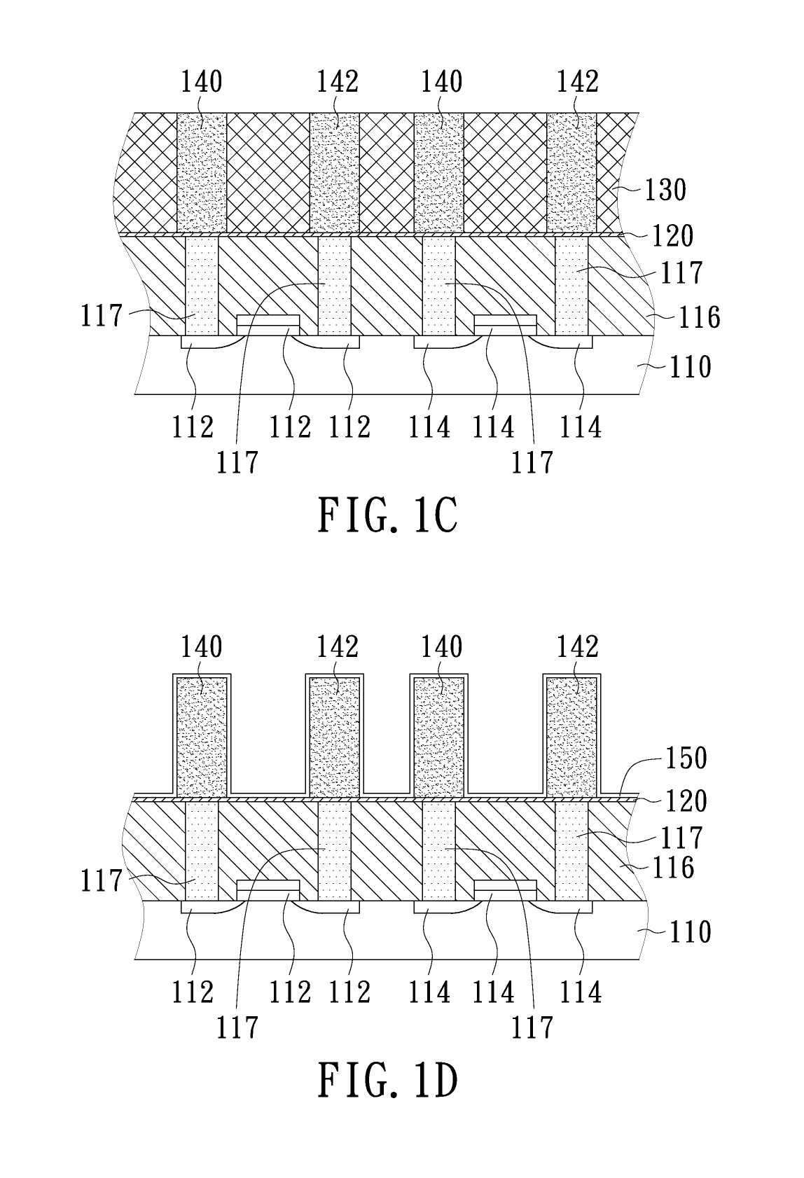

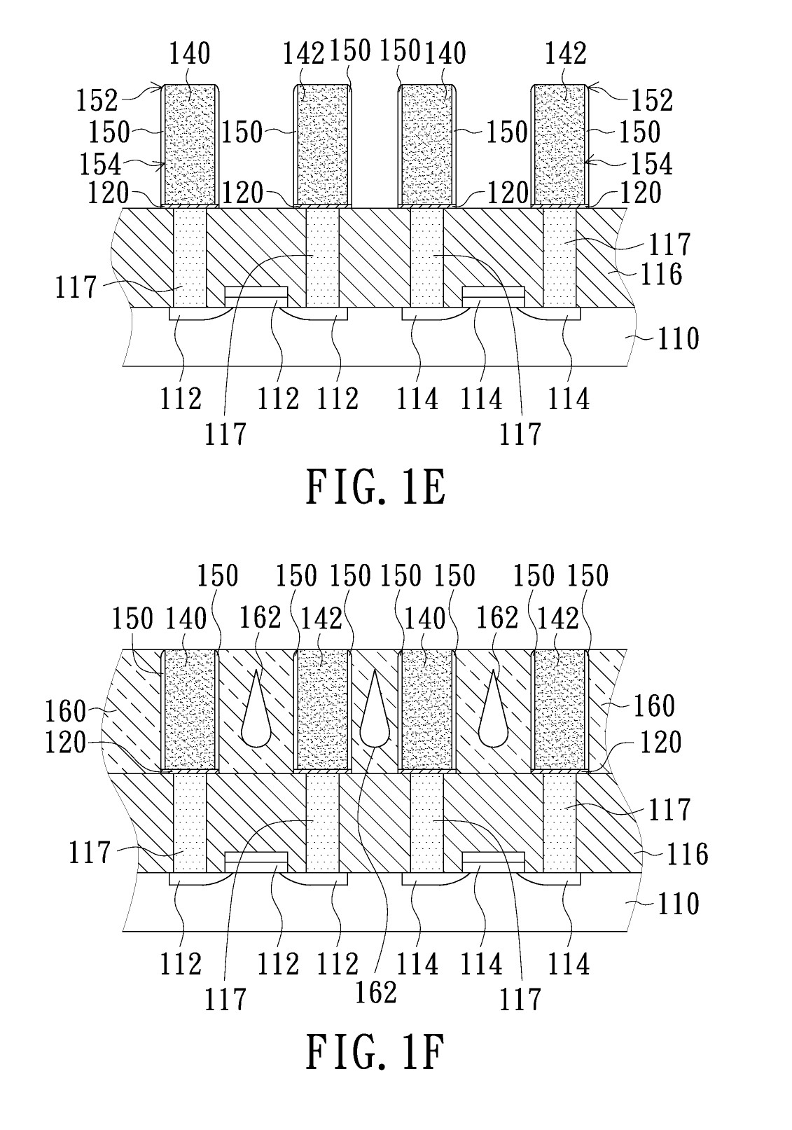

FIGS. 1A-1F are schematic diagrams illustrating a method for manufacturing metal lines in as semiconductor device in accordance with an embodiment of the present invention. As shown in FIG. 1A, a substrate 110 is provided and a first barrier layer 120 is formed on the substrate 110. Specifically, the first barrier layer 120 is formed by atomic layer deposition (ALD).

The substrate 110 is a semiconductor substrate (e.g. a silicon substrate) or a metal substrate and has been formed with transistor structures 112, 114, memory structures (not shown) or other circuit elements (not shown). These circuit elements are isolated by a dielectric layer 116 and will be electrically connected to other circuit elements through metal via plugs 117. It is to be noted that the shown semiconductor substrate 110 with the transistor structures 112 and 114, the dielectric layer and the metal via plugs 117 is only for illustration, and is not intended to limit the present invention. Numbers of the transistor structures 112, 114 and the metal via plugs 117 can be varied to meet the practical requirement, or they can be replaced by other circuit elements. Furthermore, the term “substrate” in the specification may broadly encompass a single substrate only or a substrate with circuit elements formed thereon to be interconnected. To simplify the description, the term “substrate” in the specification usually involves underlying circuits such as the transistors 112, 114, the metal via plugs 117 and the dielectric layer 116.

The material of the first barrier layer 120 may be metal (e.g. tantalum (Ta), tungsten (W), cobalt (Co), titanium (Ti) or ruthenium (Ru)), metal alloy (e.g. titanium-tungsten alloy (Ti—W)), metal nitride (e.g. titanium nitride (Ti—N), tantalum nitride (Ta—N), tungsten nitride (W—N) or niobium nitride (Nb—N)), metal carbide (e.g. titanium carbide (TiC), tantalum carbide (Ta—C), tungsten carbide (W—C)), metal oxide (e.g. ruthenium oxide (Ru—O), iridium oxide (Ir—O), manganese oxide (Mn-O), alumina (Al—O)), or an combination thereof. The first barrier layer (film) 120 may have a thickness of several nanometers and is configured to be a single layer, a composite layer or a gradient layer made from one or more of the above-mentioned materials. For example, the gradient layer may be formed by implanting carbon, nitrogen or oxygen atoms with various concentrations into the metal material along a normal direction to a surface of the substrate 110. Generally, the bottom layer of the composite layer is made of a material with higher adhesion or lower contact resistance, such as Ti/TiN composite material used in a tungsten plug process, or TaN/Ta composite material used in a copper process. It is to be noted that the first barrier layer 120 is not limited to the aforementioned materials and thickness.

Next, as shown in FIG. 1B, a sacrificial layer 130 including a photosensitive material is formed on the first barrier layer 120. Then, at least one opening 132, 134 (usually called as trenches in dual damascene process) is formed in the sacrificial layer 130 by a photolithography process including exposure, development and hard baking. The embodiment is exemplified by forming four openings 132, 134 in the sacrificial layer 130, but the number of the openings is not limited thereto. As shown, the openings 132, 134 are disposed above the transistor structures 112, 114 and the via plugs 117, and the openings 132, 134 penetrate through the sacrificial layer 130 to expose a portion of the first barrier layer 120. The openings 132, 134 may be served as trenches or vias in damascene process. Specially, the sacrificial layer 130 is made of a photoresist material or an insulating material. Therefore, the sacrificial layer 130 can be opened by the photolithography process rather than the conventional etching process, the latter of which usually causes complicated conditional control and plasma damage.

After forming the openings 132, 134 in the sacrificial layer 130, surface modification (not shown) is performed on the exposed portion of the first barrier layer 120 at the bottom areas of the openings 132, 134. The surface modification includes, for example, physical plasma bombardment, oxidation using oxidizing agent, or chemical modification method such as dipping in acid/alkali solutions or diluted hydrofluoric acid (DHF) solution.

Please refer to FIG. 1C, after performing the surface modification on the exposed portion of the first barrier layer 120 at the bottom areas of the openings 132, 134, a metal deposition process, such as electroplating process, electroless process, other wet chemical process (e.g., electrophoresis process) or supercritical fluid coating process, is performed on the exposed portion of the first barrier layer 120 to achieve bottom-to-up anisotropic growth. The metal lines 140, 142 grow to near the top area (entrance) of the opening 132, 134. Through controlling the growing height of the metal lines, the subsequent chemical mechanical polishing (CMP) process may be omitted in the present invention. However, it is understood that the chemical mechanical polishing process may be still performed to remove excess metal material after the metal deposition step for planarization purpose.

The modified first barrier layer 120 allows uniform growth or deposition of the metal material due to the wetting effect of the modified surface. The metal lines 140, 142 may include a material of silver, tungsten, molybdenum, ruthenium, nickel or an alloy thereof, but the present invention is not limited thereto.

Please refer to FIG. 1D, after the formation of the metal lines 140, 142, the sacrificial layer 130 is stripped off or removed. Then, a second barrier layer 150 is formed on the resulting structure, e.g. tops of the metal lines 140, 142, sidewalls of the metal lines 140, 142 and the exposed portion of the first barrier layer 120. The second barrier layer 150 may be formed by atomic layer deposition or other suitable method. It is to be noted that the second barrier layer 150 is used for inhibiting the metal diffusion as well as for enhancing the adhesion between the metal lines and a subsequently-formed insulating layer. The material of the second barrier layer 150 may be metal (e.g. tantalum (Ta), tungsten (W), cobalt (Co), titanium (Ti) or ruthenium (Ru)), metal alloy (e.g. titanium-tungsten alloy (Ti—W)), metal nitride (e.g. titanium nitride (Ti—N), tantalum nitride (Ta—N), tungsten nitride (W—N) or niobium nitride (Nb—N)), metal carbide (e.g. titanium carbide (TiC), tantalum carbide (Ta—C), tungsten carbide (W—C)), metal oxide (e.g. ruthenium oxide (Ru—O), iridium oxide (Ir—O), manganese oxide (Mn—O) or alumina (Al—O)), or an combination thereof. The materials of the first barrier layer 120 and the second barrier layer 150 may be the same or different.

Please refer to FIG. 1E. Portions of the first barrier layer 120 and the second barrier layer 150 are removed by anisotropic-etching, thereby remaining the second barrier layer 150 on the sidewalls of the metal lines 140, 142, and remaining the first barrier layer 120 under the second barrier layer 150 and the metal lines 140, 142. Specifically, the remained second barrier layer 150, called as barrier spacers, gets thicker in the lower portion. In other words, the thicker portion 154 of the barrier spacer 150 is near the first barrier layer 120. A taper-shaped end 152 of the barrier spacer 150 is near an upper corner of the metal lines 140, 142 and in contact with a top portion of the metal line 140, 142.

Please refer to FIG. 1F, an insulating layer 160 is formed over the substrate 110 formed with the metal lines 140, 142, the first barrier layer 120, and the barrier spacers 150 to isolate the metal lines 140, 142 from each other. Then, a planarization process such as chemical mechanical polishing (CMP) process is performed on the insulating layer 160. When the spacing between the two adjacent barrier spacers 150, which define a space for accommodating the insulating layer 160 along the cross-sectional view in FIG. 1F, is too small to tolerate poor step coverage of the insulating material, an air gap 162 will be formed in the insulating layer 160 between the two adjacent barrier spacers 150 due to a non-conformal property of the insulating material. For example, when the spacing is less than 30 nm, the insulating layer 160 with non-conformal profile is probably formed with the air gap 162 contained. It is understood that the position of the air gap 162 shown in FIG. 1F is for the exemplary purpose only, and the present invention is not limited thereto. Hence, with the air gap 162 in the insulating layer 160 rather than the void in the metal line 140, the metal line structure provided in the present invention has lower resistance and parasitic capacitance, and the electrical performance of the semiconductor device using the metal line structure is improved. The insulating layer 160 may be made of oxide or nitride, but the present invention is not limited thereto. The metal lines 140, 142 and the via plugs 117 achieve interconnection between the circuit components or conductors at both sides of the insulating layer 160. Moreover, the above-mentioned via plugs 117 may be formed according to the manufacturing method of the present invention, too.

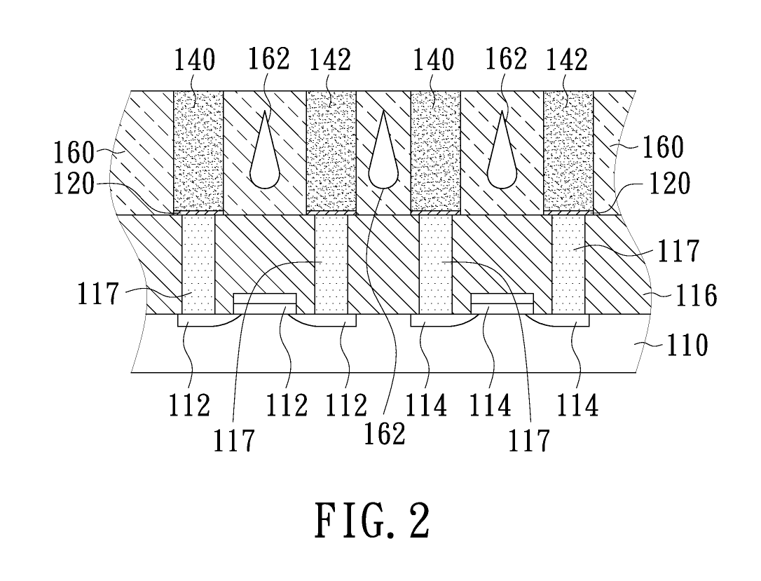

Another method for manufacturing metal lines, similar to that illustrated in FIGS. 1A-1F but without the step of forming the second barrier layer 150 (FIG. 1D), is also provided. Specifically, after forming the metal lines 140, 142 and removing the sacrificial layer 130, a portion of the first barrier layer 120 is removed by anisotropic-etching, and the portion of the first barrier layer 120 under the metal lines 140, 142 is remained. No second barrier layer 150 is formed before the anisotropic-etching step. Then, an insulating layer 160 is formed over the substrate 110 formed with the metal lines 140, 142 and the first barrier layer 120. The resulting metal line structure is illustrated in FIG. 2. Because the second barrier layer 150 around the metal lines 140, 142 as diffusion barrier is omitted, the material of the metal lines 140, 142 should have lower diffusion coefficient. Otherwise, a metal additive such as aluminum, manganese, ruthenium or tungsten, which reacts automatically and easily with the insulating layer 160 to form oxide or nitride on an interface between the metal lines 140, 142 and the insulating layer 160, may be introduced into the metal lines 140, 142. Therefore, a protective layer (not shown) of metal oxide or metal nitride is formed and covering the sidewalls of the metal lines 140, 142 to overcome the metal diffusion problem. Besides, an air gap 162 is also formed in the non-conformal insulating layer 160 between the two metal lines 140, 142 when the spacing becomes narrower.

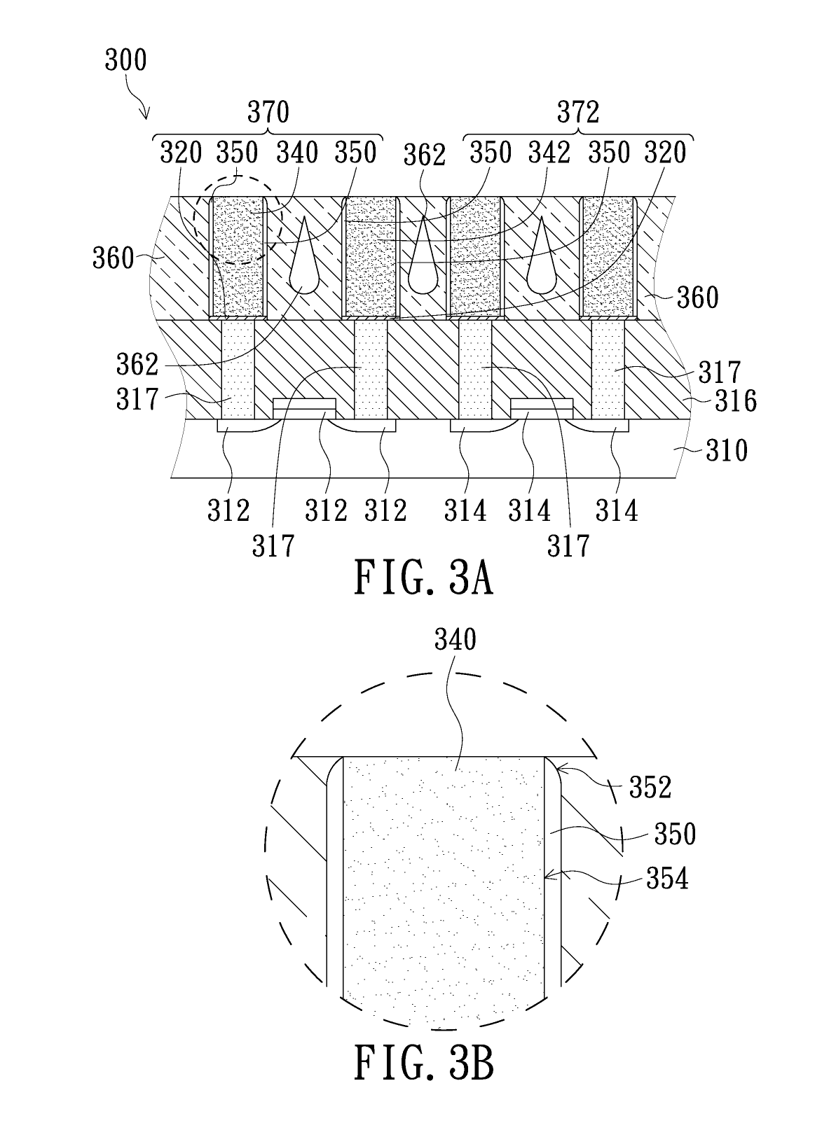

FIG. 3A is a schematic diagram illustrating a semiconductor device in accordance with another embodiment of the present invention. As shown, the semiconductor device 300 includes a substrate 310, an insulating layer 360 formed on the substrate 310, a first metal line structure 370 and a second metal line structure 372 formed in the insulating layer 360 by a damascene process. The substrate 310 is similar to the substrate 110 in the first embodiment, and no redundant detail is to be given herein. The substrate 310 has been, for example, formed with transistor structures 312, 314, a dielectric layer 316 and metal via plugs 317. Although there are four metal line structures 370, 372 shown in FIG. 3A, it is understood that the actual number may vary according to the practical requirement.

The first metal line structure 370 and the second metal line structure 372 both include metal lines 340, 342, a first barrier layer 320 and a second barrier layer (barrier spacer) 350. The first barrier layer 320 is disposed between the broadly defined substrate 310 (including the transistor structures 312, 314, the metal via plugs 317 and the dielectric layer 316) and the metal lines 340, 342. The second barrier layer 350 is disposed on sidewalls of the metal lines 340, 342 and an exposed portion of the first barrier layer 320. FIG. 3B is an enlarged diagram of the dashed circle area in FIG. 3A. The second barrier layer 350 is a taper-shaped sidewall spacer whose thicker portion 354 is near the first barrier layer 320. A taper-shaped (rounded) end 352 thereof is near an upper corner or a top portion of the metal line 340, 342.

It is to be noted that an air gap 362 is formed in and defined by the non-conformal insulating layer 360 between the first metal line structure 370 and the second metal line structure 372. The spacing between the first metal line structure 370 and the second metal line structure 372 is usually less than 30 nm. When the pitch (line width and spacing) becomes narrower, even less than 20 nm, the present method can still provide semiconductor devices with high electrical performance. The materials of the first barrier layer 320, the second barrier layer 350 and the metal lines 340, 342 have been described above with reference to the first barrier layer 120, the second barrier layer 150 and the metal lines 140, 142, respectively. No redundant details are to be given herein.

In summary, by using the photolithography process to form the openings for the metal lines, complicated etching processes and the accompanying plasma damage are avoided. Furthermore, the present invention adopts the electroplating process, the electroless plating process or other wet chemical processes (e.g. the electrophoretic process) to grow the metal line on the first barrier layer at the bottom areas of the openings (trenches or vias) in a bottom-to-up manner. Therefore, the metal material does not accumulate on the sidewalls to narrow the openings, and the internal voids are never observed. In addition, the air gaps encapsulated in the insulating layer between two closely spaced metal lines can effectively reduce the parasitic capacitance. Therefore, compared to the conventional metal line structure, the metal line structure according to the present invention has both lower resistance and lower parasitic capacitance, thereby enhancing the electrical performance and improving the delay phenomenon of the semiconductor device.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for manufacturing metal lines in a semiconductor device, comprising:
providing a substrate;
forming a first barrier layer on the substrate;
forming a sacrificial layer on the first barrier layer;
forming at least one opening in the sacrificial layer, wherein the at least one opening penetrates through the sacrificial layer to expose a first portion of the first barrier layer;
depositing a metal material on the first portion of the first barrier layer to form at least one metal line in the at least one opening;
removing the sacrificial layer to expose a second portion of the first barrier layer and forming a second barrier layer on a top area and a sidewall of the metal line and the second portion of the first barrier layer;
etching the second barrier layer and the first barrier layer while remaining a portion of the second barrier layer on the sidewall of the metal line as a barrier spacer and remaining a third portion of the first barrier layer under the barrier spacer and the metal line; and
forming an insulating layer on the substrate.

2. The method according to claim 1, wherein the barrier spacer has a taper-shaped end near an upper corner of the metal line.

3. The method according to claim 1, wherein the metal line and the barrier spacer is formed on the remained third portion of the first barrier layer.

4. The method according to claim 1, wherein the metal material is deposited on the first portion of the first barrier layer by an electroplating process, an electroless plating process, an electrophoretic process or a supercritical fluid coating process with a bottom-to-up anisotropic growth from the first barrier layer toward an entrance of the at least one opening

5. The method according to claim 1, after the step of forming the sacrificial layer, the method further comprises steps of:
forming a plurality of openings in of the sacrificial layer, wherein the openings penetrate through the sacrificial layer to expose portions of the first barrier layer;
depositing the metal material on the portions of the first barrier layer to form a plurality of metal lines in the openings, and
remaining portions of the second barrier layer on sidewalls of the metal lines as barrier spacers during the etching step,
wherein when a spacing between two adjacent barrier spacers, which defining a space for accommodating the insulating layer, is less than 30 nm, an air gap is formed in the insulating layer between the two adjacent barrier spacers.

6. The method according to claim 1, wherein the metal line is made of silver, tungsten, molybdenum, ruthenium, nickel or an alloy thereof.

7. A method for manufacturing metal lines in a semiconductor device, comprising:
providing a substrate;
forming a barrier layer on the substrate;
forming a sacrificial layer on the barrier layer;
forming at least one opening in the sacrificial layer, wherein the opening penetrates through the sacrificial layer to expose a first portion of the barrier layer;
depositing a metal material on the first portion of the barrier layer to form at least one metal line in the at least one opening;
removing the sacrificial layer and a second portion of the barrier layer thereunder, while remaining the first portion of the barrier layer; and
forming an insulating layer on the substrate.

8. The method according to claim 7, wherein the sacrificial layer is made of a photoresist material or an insulating material.

9. The method according to claim 7, wherein the metal material is deposited on the first portion of the barrier layer by an electroplating process, an electroless plating process, an electrophoretic process or a super critical fluid coating process with a bottom-to-up anisotropic growth from the barrier layer toward an entrance of the at least one opening

10. The method according to claim 7, further comprising a step of performing a surface modification process on the first portion of the barrier layer.

11. The method according to claim 7, after the step of forming the sacrificial layer, the method further comprises steps of:
forming a plurality of openings in the sacrificial layer, wherein the openings penetrate through the sacrificial layer to expose portions of the barrier layer; and
depositing the metal material on the portions of the barrier layer to form a plurality of metal lines in the openings,
wherein when a spacing between two adjacent metal lines is less than 30 nm, an air gap is formed in the insulating layer between the two adjacent metal lines.

12. The method according to claim 7, wherein the substrate is a semiconductor substrate or a metal substrate formed with a transistor structure or a memory structure.

13. A method for manufacturing metal lines in a semiconductor device, comprising:
providing a substrate;
forming a barrier layer on the substrate;
forming a sacrificial layer on the barrier layer;
forming at least one opening in the sacrificial layer, wherein the opening penetrates through the sacrificial layer to expose a first portion of the barrier layer; and
forming a metal material on the first portion of the barrier layer with a bottom-to-up anisotropic growth from the barrier layer toward an entrance of the at least one opening to form at least one metal line in the at least one opening.

14. The method according to claim 13, further comprising steps of:
removing the sacrificial layer and a second portion of the barrier layer thereunder, while remaining the first portion of the barrier layer; and
forming an insulating layer on the substrate.

15. The method according to claim 14, wherein before the step of forming the insulating layer, the method further comprises a step of forming a barrier spacer on a sidewall of the metal line.

16. The method according to claim 14, wherein an air gap is formed in the insulating layer during the step of forming the insulating layer when a spacing between the metal line and another metal line is less than 30 nm.

17. The method according to claim 13, wherein the sacrificial layer is made of a photoresist material or an insulating material.

18. The method according to claim 13, wherein the metal material is deposited on the first portion of the barrier layer by an electroplating process, an electroless plating process, an electrophoretic process or a supercritical fluid coating process after performing a surface modification process on the first portion of the barrier layer.

19. The method according to claim 18, wherein the surface modification process is performed by physical plasma bombardment, oxidation using an oxidizing agent, or a chemical modification method.

20. The method according to claim 19, wherein the chemical modification method is performed with an acid/alkali solution or a diluted hydrofluoric acid (DHF) solution.
